(19) United States
(12) Patent Application Publication
(10) Pub. No.: US 2015/0333258 A1
(43) Pub. Date: Nov. 19, 2015

(54) Non-volatile memory device comprising a ferroelectric film and a paraelectric film.

(71) Applicant: Kabushiki Kaisha Toshiba, Minato-ku (JP)

(72) Inventors: Shosuke FUJII, Kuwana (JP); Takayuki Ishikawa, Yokkaichi (JP)

(73) Assignee: Kabushiki Kaisha Toshiba, Minato-ku (JP)

(21) Appl. No.: 14/808,494

(22) Filed: Jul. 24, 2015

Related U.S. Application Data
(63) Continuation of application No. PCT/JP2014/067583, filed on Jul. 1, 2014.

(30) Foreign Application Priority Data
Sep. 20, 2013 (JP) 2013-195114

(51) Int. Cl. H01L 45/00

(52) U.S. Cl. CPC H01L 45/146; H01L 45/147; H01L 45/1233

(57) ABSTRACT

A non-volatile memory device of an embodiment includes: a first conductive layer; a second conductive layer; a ferroelectric film provided between the first conductive layer and the second conductive layer; and a paraelectric film provided between one of the first conductive layer and the second conductive layer, and the ferroelectric film, the paraelectric film having film thickness of 1.5 nm or more and 10 nm or less, and the paraelectric film having a dielectric constant higher than the ferroelectric film.

### CROSS-REFERENCE TO RELATED APPLICATION

This application is continuation application of, and claims the benefit of priority from the International Application PCT/JP2014/067583, filed Jul. 1, 2014, which claims the benefit of priority from Japanese Patent Application No. 2013-195114, filed on Sep. 20, 2013, the entire contents of all of which are incorporated herein by reference.

### FIELD

Embodiments described herein relate generally to a non-volatile memory device.

### BACKGROUND

Floating gate type flash memories have become widely used as non-volatile memory devices for storing large volume data. Currently, cost reduction per bit and an increase in capacity of storage data have been in progress by scaling down of memory cells. Further improvement of the scaling-down is required.

However, to further scale down memory cells of the flash memories, there are many issues to be solved, such as suppression of short-channel effect, inter-cell interference, and variation in characteristics of cells. Therefore, practical use of a new non-volatile memory device replacing the conventional floating gate type flash memories is expected.

In recent years, as the new non-volatile memory device replacing the conventional floating gate type flash memories, a memory using a two-terminal resistance change element has been developed. The resistance change element is a promising candidate as a next-generation large-capacity non-volatile memory device from the perspective of a low-voltage operation, high-speed switching, and possibilities of further scaling-down. Among resistance change elements, a ferroelectric tunnel junction (FTJ) using a ferroelectric thin film can realize a low current, low-voltage driving, and the high-speed switching, and thus has drawn attention.

When the large-capacity non-volatile memory device is realized with the two-terminal resistance change element, a memory cell structure in which memory cells are provided in regions where upper and lower electrode wires intersect with each other, a so-called cross-point structure is employed. In the cross-point structure, it is desired that each of the memory cells has a rectification function in order to suppress a stray current flowing through the memory cells.

### BRIEF DESCRIPTION OF THE DRAWINGS

FIG. 1 is a schematic cross-sectional view of a memory cell of a non-volatile memory device of a first embodiment;

FIG. 2 is a conceptual diagram of a memory cell array of the non-volatile memory device of the first embodiment;

FIGS. 3A and 3B are explanatory diagrams of a resistance change function of the non-volatile semiconductor device of the first embodiment;

FIG. 4 is simulation results of current-voltage characteristics of a memory cell of the first embodiment;

FIGS. 5A to 5C are explanatory diagrams of a rectification function of the non-volatile semiconductor device of the first embodiment;

FIG. 6 is a simulation result of a relationship between a rectification ratio of a memory cell of the first embodiment and film thickness of a paraelectric film;

FIG. 7 is a schematic cross-sectional view of a memory cell of a non-volatile memory device of a second embodiment;

FIGS. 8A to 8C are explanatory diagrams of a rectification function of the non-volatile semiconductor device of the second embodiment;

FIG. 9 is simulation results of current-voltage characteristics of a memory cell of the second embodiment;

FIG. 10 is a simulation result of a relationship between a rectification ratio of a memory cell of the second embodiment and film thickness of a paraelectric film;

FIG. 11 is a schematic cross-sectional view of a memory cell of a non-volatile memory device of a third embodiment; and

FIG. 12 is a simulation result of a relationship between a rectification ratio of a memory cell of the third embodiment and film thickness of a paraelectric film.

### DETAILED DESCRIPTION

A non-volatile memory device of an embodiment includes: a first conductive layer; a second conductive layer; a ferroelectric film provided between the first conductive layer and the second conductive layer; and a paraelectric film provided between one of the first conductive layer and the second conductive layer, and the ferroelectric film, the paraelectric film having film thickness of 1.5 nm or more and 10 nm or less, and the paraelectric film having a dielectric constant higher than the ferroelectric film.

In the present specification, “ferroelectrics” mean a substance having spontaneous polarization even if an electric field is not applied from an outside, and having reverse polarization when the electric field is applied from an outside. Further, in the present specification, “paraelectrics” mean a substance in which polarization is caused when an electric field is applied, and the polarization disappears when the electric field is removed.

Hereinafter, embodiments of the present disclosure will be described with reference to the drawings.

### First Embodiment

A non-volatile memory device of the present embodiment includes a first conductive layer, a second conductive layer, a ferroelectric film provided between the first conductive layer and the second conductive layer, and a paraelectric film having film thickness of from 1.5 nm or more to 10 nm or less, and a dielectric constant higher than the ferroelectric film, and provided between one of the first conductive layer and the second conductive layer, and the ferroelectric film.

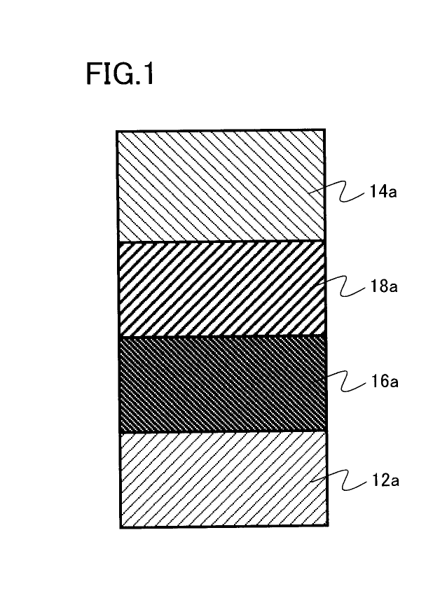

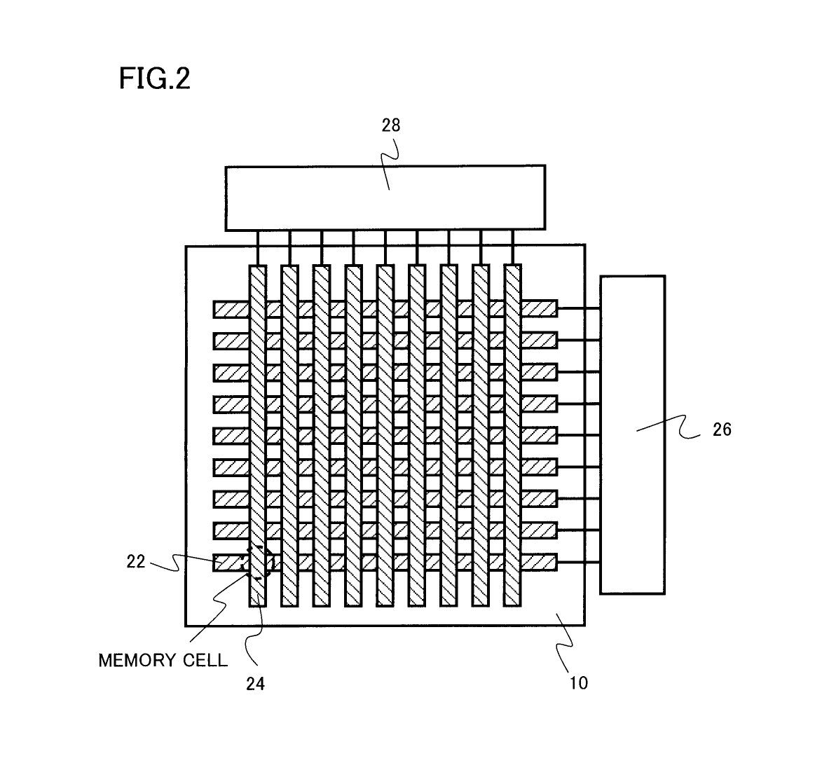

FIG. 1 is a schematic cross-sectional view of a memory cell of a non-volatile memory device of the present embodiment. FIG. 2 is a conceptual diagram of a memory cell array of the non-volatile memory device of the present embodiment. FIG. 1 illustrates a cross section of one memory cell indicated by a dotted line circle in the memory cell array of FIG. 2, for example.

The memory cell array of the non-volatile memory device of the present embodiment includes a plurality of first wires 22, and a plurality of second wires 24 intersecting with the first wires 22, on a semiconductor substrate 10 through an insulating layer, for example. The second wires 24 are provided on upper layers of the first wires 22.

The first wires 22 are word lines, and the second wires 24 are bit lines. The first wires 22 and the second wires 24 are, for example, metal wires.

A plurality of memory cells is provided in regions where the first wires 22 and the second wires 24 intersect with each other. The non-volatile memory device of the present embodiment includes a so-called cross-point structure.

Each of the first wires 22 is connected to a first control circuit 26. Further, each of the second wire 24 is connected to a second control circuit 28.

The first control circuit 26 and the second control circuit 28 include, for example, a function to select a desired memory cell, write data to the memory cell, read data from the memory cell, erase data of the memory cell, and the like. The first control circuit 26 and the second control circuit 28 are configured from an electronic circuit using a semiconductor device, for example.

As illustrated in FIG. 1, the memory cell is a two-terminal FTJ sandwiched by a lower electrode (first conductive layer) 12a and an upper electrode (second conductive layer) 14a. The memory cell includes a ferroelectric film 16a between the lower electrode 12a and the upper electrode 14a. Further, the memory cell includes a paraelectric film 18a between the ferroelectric film 16a and the upper electrode 14a.

The lower electrode 12a is lanthanum strontium manganese oxide (LSMO). LSMO has a composition of La₁₋ₓSrₓMnO₃ (0<x<1). The upper electrode 14a is titanium nitride (TiN).

Note that the first wire 22 and the lower electrode 12a, or the second wire 24 and the upper electrode 14a may be made common. That is, the first wire 22 itself may be the lower electrode 12a, or the second wire 24 itself may be the upper electrode 14a.

The ferroelectric film 16a is barium titanate (BTO). The dielectric constant of BTO is 90. Further, the film thickness of the ferroelectric film 16a is desirably from 1.0 nm or more to 10 nm or less. The film thickness of the ferroelectric film 16a is more desirably 2.0 nm or more.

The paraelectric film 18a is strontium titanate (STO). The dielectric constant of STO is 200. The dielectric constant of the paraelectric film 18a is higher than that of the ferroelectric film 16a. Further, the band gap of the paraelectric film 18a is narrower than that of the ferroelectric film 16a. The film thickness of the paraelectric film 18a is from 1.5 nm or more to 10 nm or less. The film thickness of the paraelectric film 18a is more desirably 2.0 nm or more.

Further, a sum of the film thickness of the ferroelectric film 16a and the film thickness of the paraelectric film 18a is desirably 10 nm or less.

Hereinafter, functions and effects of the non-volatile memory device of the present embodiment will be described.

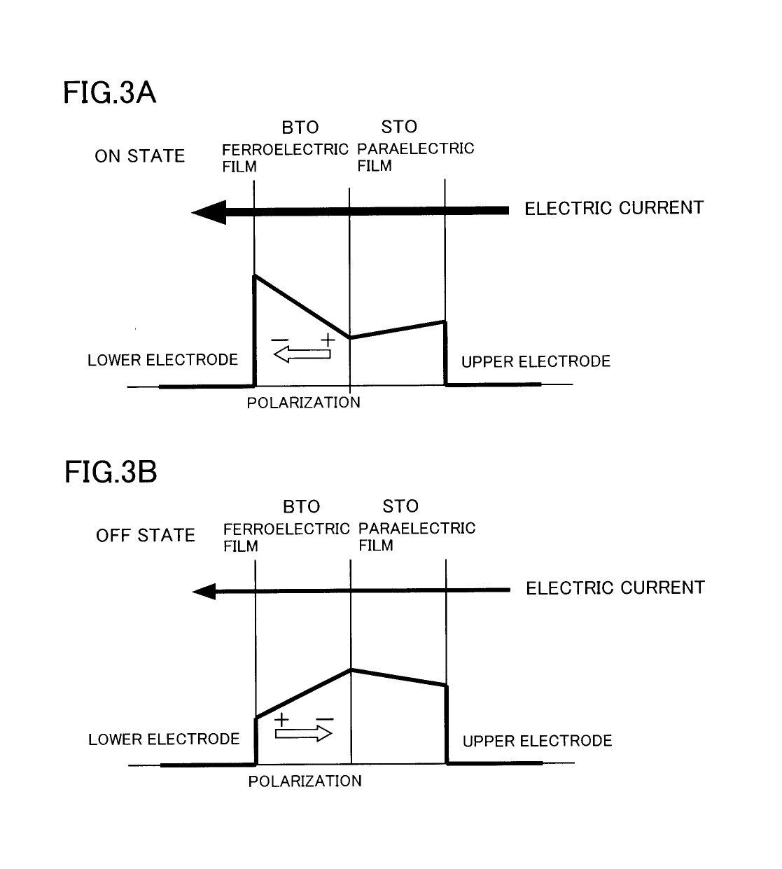

FIGS. 3A and 3B are explanatory diagrams of a resistance change function of the non-volatile semiconductor device of the present embodiment. FIG. 3A illustrates a band structure of a memory cell in a low resistance state (ON state). FIG. 3B illustrates a band structure of a memory cell in a high resistance state (OFF state).

FIGS. 3A and 3B illustrates Fermi levels of the lower electrode 12a and the upper electrode 14a, and lower ends of conductors of the ferroelectric film 16a and the paraelectric film 18a, by the solid thick lines. Further, a flow of a current is illustrated by the black arrow, and a polarizing direction of the ferroelectric film 16a is illustrated by the white arrow.

When the ferroelectric film 16a is polarized into the direction illustrated in FIG. 3A, the band structure of the BTO/STO downwardly protrudes, and a barrier for allowing electrons to perform tunneling becomes low. Therefore, when a voltage is applied between the lower electrode 12a and the upper electrode 14a in that state, a current amount flowing in the memory cell becomes relatively large. Therefore, the memory cell becomes the low resistance state (ON state).

In contrast, when the ferroelectric film 16a is polarized into the direction illustrated in FIG. 3B, the band structure of the BTO/STO upwardly protrudes, and the barrier for allowing electrons to perform tunneling becomes high. Therefore, when a voltage is applied between the lower electrode 12a and the upper electrode 14a in that state, the current amount flowing in the memory cell becomes relatively small. Therefore, the memory cell becomes the high resistance state (OFF state).

As described above, the resistance of the memory cell is changed according to the polarizing direction of BTO as the ferroelectric film 16a. For example, if the high resistance state is defined as “0”, and the low resistance state is defined as “1”, a non-volatile memory cell can be realized.

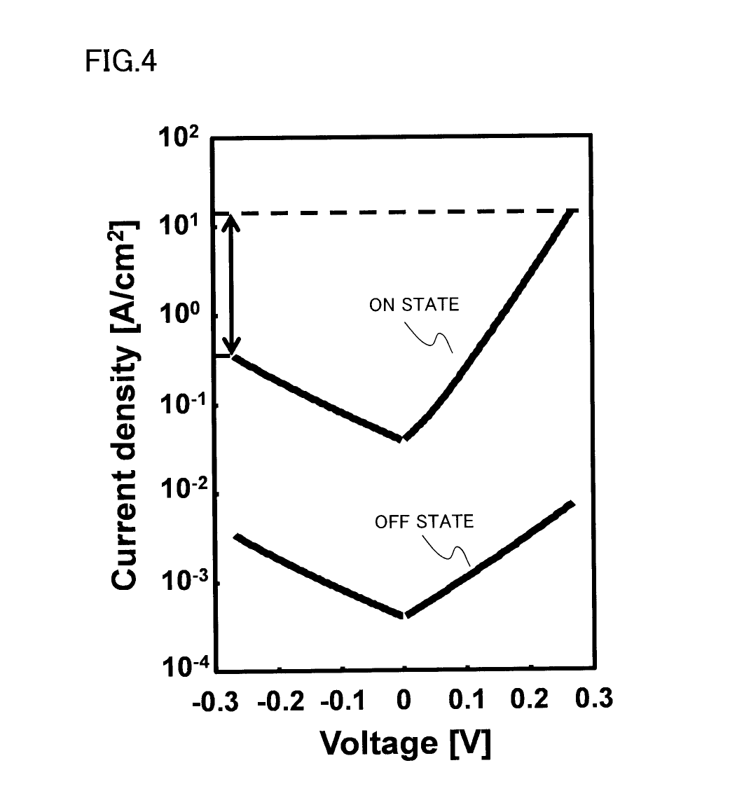

FIG. 4 is simulation results of current-voltage characteristics (I-V characteristics) of a memory cell of the present embodiment. The horizontal axis represents a voltage applied between the electrodes, and the vertical axis represents a current value flowing between the electrodes.

The simulation results are calculated where the film thickness of BTO is 2.5 nm, and the film thickness of STO is 2.0 nm. A voltage applying direction of when the polarization of the high resistance state (OFF state) is formed is a positive voltage. A voltage applying direction of when the polarization of the low resistance state (ON state) is formed is a negative voltage. The simulation results of both cases of the low resistance state (ON state) and the high resistance state (OFF state) are calculated.

As illustrated in FIG. 4, in the memory cell of the present embodiment, the I-V characteristics are asymmetrical in the positive and negative voltage directions. That is, the current values are different by the amount illustrated by the two-way arrow in the drawing between the case of applying the positive voltage between the electrodes, and the case of applying the negative voltage between the electrodes, in the ON state. Therefore, the memory cell of the present embodiment has a rectification function in the ON state.

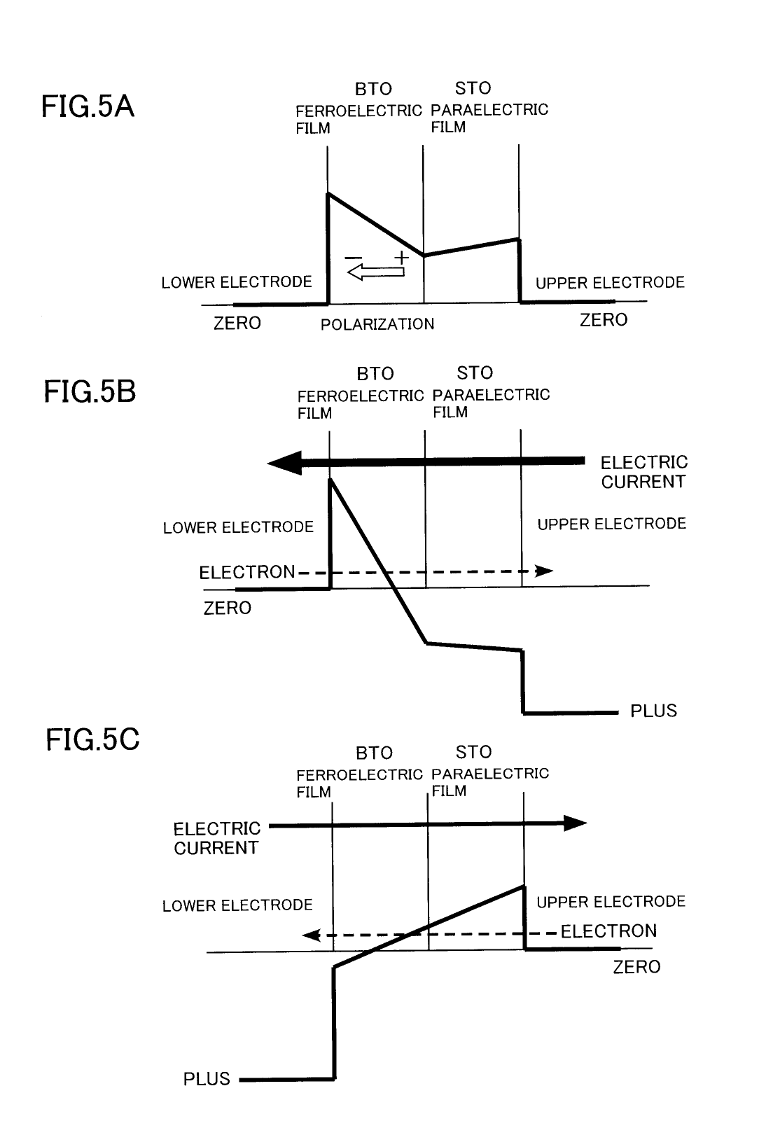

FIGS. 5A to 5C are explanatory diagrams of the rectification function of the non-volatile semiconductor device of the present embodiment. FIG. 5A illustrates a band structure of a memory cell of when a voltage is not applied between the electrodes. FIG. 5B illustrates a band structure of a memory cell of when the positive voltage is applied between the electrodes. FIG. 5C illustrates a band structure of a memory cell of when the negative voltage is applied between the electrodes.

FIGS. 5A to 5C illustrate Fermi levels of the lower electrode 12a and the upper electrode 14a, and lower ends of conductors of the ferroelectric film 16a and the paraelectric film 18a, by the solid thick lines. Further, a flow of a current is illustrated by the black arrow, and a polarizing direction of the ferroelectric film 16a is illustrated by the white arrow.

The dielectric constant of STO as the paraelectric film 18a is higher than that of BTO as the ferroelectric film 16a. In other words, the dielectric constant of the ferroelectric film 16a is lower than that of the paraelectric film 18a. According to the Maxwell's equations, a relationship that the product of the dielectric constant and the electric field is constant between the ferroelectric film 16a and the paraelectric film 18a is established. Therefore, as for the voltage applied between the upper electrode 14a and the lower electrode 12a, a higher ratio of voltage is applied to the ferroelectric film 16a having the lower dielectric constant. Therefore, change of the band structure of the paraelectric film 18a due to application of the voltage is smaller than that of the ferroelectric film 16a.

Therefore, as illustrated in FIG. 5B, when the positive voltage is applied to the upper electrode 14a, a barrier for allowing electrons to perform tunneling becomes relatively low. Therefore, a relatively large current flows from the upper electrode 14a to the lower electrode 12a. Meanwhile, when the positive voltage is applied to the lower electrode 12a, as illustrated in FIG. 5C, the change of the band structure of the paraelectric film 18a is small. Therefore, the barrier for allowing electrons to perform tunneling becomes relatively high. Therefore, a relatively small current flows from the lower electrode 12a to the upper electrode 14a.

When the memory cells configured from the two-terminal resistance change element are disposed in the cross-point structure, like the non-volatile memory device of the present embodiment, it is important to suppress a current noise called stray current. Therefore, a rectifying element that has the rectification function is provided to the resistance change element in series, in addition to the resistance change element.

The memory cell using the FTJ of the present embodiment also has the rectification function, in addition to the resistance change function. Therefore, even when a memory cell array in the cross-point structure is employed, it is not necessary to provide the rectifying element, in addition to the resistance change element. Therefore, the memory cell can be scaled down. Further, manufacturing of the memory cell becomes easy.

In the present embodiment, regarding the voltage applied between the upper electrode 14a and the lower electrode 12a, a higher ratio of voltage is applied to the ferroelectric film 16a, as described above. Therefore, polarization reversal of the ferroelectric film 16a becomes easy.

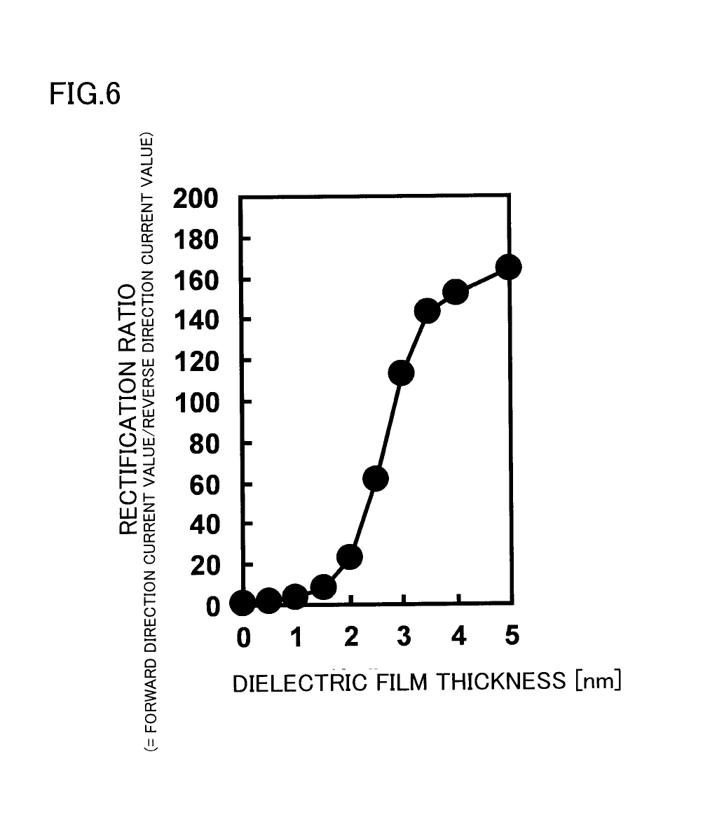

FIG. 6 is a simulation result of a relationship between a rectification ratio of a memory cell of the present embodiment, and film thickness of a paraelectric film. The horizontal axis represents the film thickness of the paraelectric film, and the vertical axis represents the rectification ratio. The rectification ratio is a ratio of a forward direction current value and a reverse direction current value read out at ±0.3 V. Note that the forward direction current is a current value in the voltage applying direction of when the polarization in the high resistance state is formed, and the reverse direction current is a current value in the voltage applying direction of when the polarization in the low resistance state is formed. The film thickness of BTO is fixed to 2.5 nm, and the film thickness of STO is changed at every 0.5 nm, and simulation is conducted.

As is clear from FIG. 6, when the film thickness of the paraelectric film 18a is thinner than 1.5 nm, rectification properties are not remarkable. However, when the film thickness is 1.5 nm or more, remarkable rectification properties begin to be exerted. This is because the paraelectric film 18a does not sufficiently function as the barrier for electrons if the film thickness is not a fixed value or more.

Therefore, the film thickness of the paraelectric film 18a should be 1.5 nm or more. The film thickness of the paraelectric film 18a is desirably 2.0 nm or more, and more desirably 2.5 nm or more, from the perspective of enhancement of the rectification properties. Further, the film thickness of the paraelectric film 18a is desirably 10 nm or less. If the film thickness exceeds the above range, a tunneling current does not flow, and a sufficient current value may not be able to be obtained when data is read out.

As described above, the film thickness of the ferroelectric film 16a is desirably from 1.0 nm or more to 10 nm or less. The film thickness of the ferroelectric film 16a is more desirably 2.0 nm or more. If the film thickness falls below the above range, stable and uniform ferroelectricity may not be able to be exerted. Further, if the film thickness exceeds the above range, the tunneling current does not flow, and the sufficient current value may not be able to be obtained when data is read out.

Further, as described above, the sum of the film thickness of the ferroelectric film 16a and the film thickness of the paraelectric film 18a is desirably 10 nm or less. If the film thickness exceeds this range, the tunneling current does not flow, and the sufficient current value may not be able to be obtained when data is read out.

As described above, according to the present embodiment, a non-volatile memory device including an FTJ having a resistance change function and a rectification function can be realized. Therefore, a non-volatile memory device in which scale-down of memory cells is easy can be realized.

### Second Embodiment

A non-volatile memory device of the present embodiment is similar to that of the first embodiment except that materials of a first conductive layer, a ferroelectric film, and a paraelectric film are different. Therefore, description is omitted about contents overlapping with those of the first embodiment.

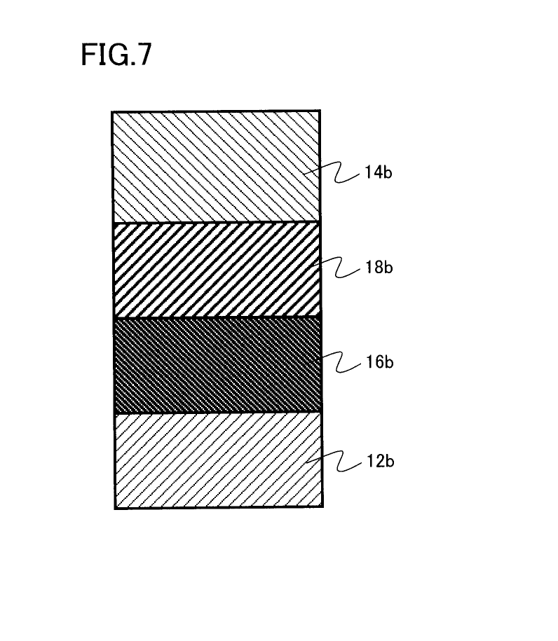

FIG. 7 is a schematic cross-sectional view of a memory cell of a non-volatile memory device of the present embodiment.

As illustrated in FIG. 7, the memory cell is a two-terminal FTJ sandwiched by a lower electrode (first conductive layer) 12b and an upper electrode (second conductive layer) 14b. The memory cell includes a ferroelectric film 16b between the lower electrode 12b and the upper electrode 14b. Further, the memory cell includes a paraelectric film 18b between the ferroelectric film 16b and the upper electrode 14b.

The lower electrode 12b and the upper electrode 14b are titanium nitride (TiN).

The ferroelectric film 16b is hafnium oxide (HfSiO) containing silicon (Si). The dielectric constant of the hafnium oxide containing silicon (Si) is 11. Note that the hafnium oxide may contain at least one element selected from the group consisting of zircon (Zr), aluminum (Al), yttrium (Y), strontium (Sr), and gadolinium (Gd), other than Si. By containing of the above elements, ferroelectricity can be more easily exerted.

The paraelectric film 18b is lanthanum aluminum oxide (LAO). The dielectric constant of LAO is 30. The dielectric constant of the paraelectric film 18b is higher than that of the ferroelectric film 16b. Further, the band gap of the paraelectric film 18b is narrower than that of the ferroelectric film 16b.

Hereinafter, functions and effects of the non-volatile memory device of the present embodiment will be described.

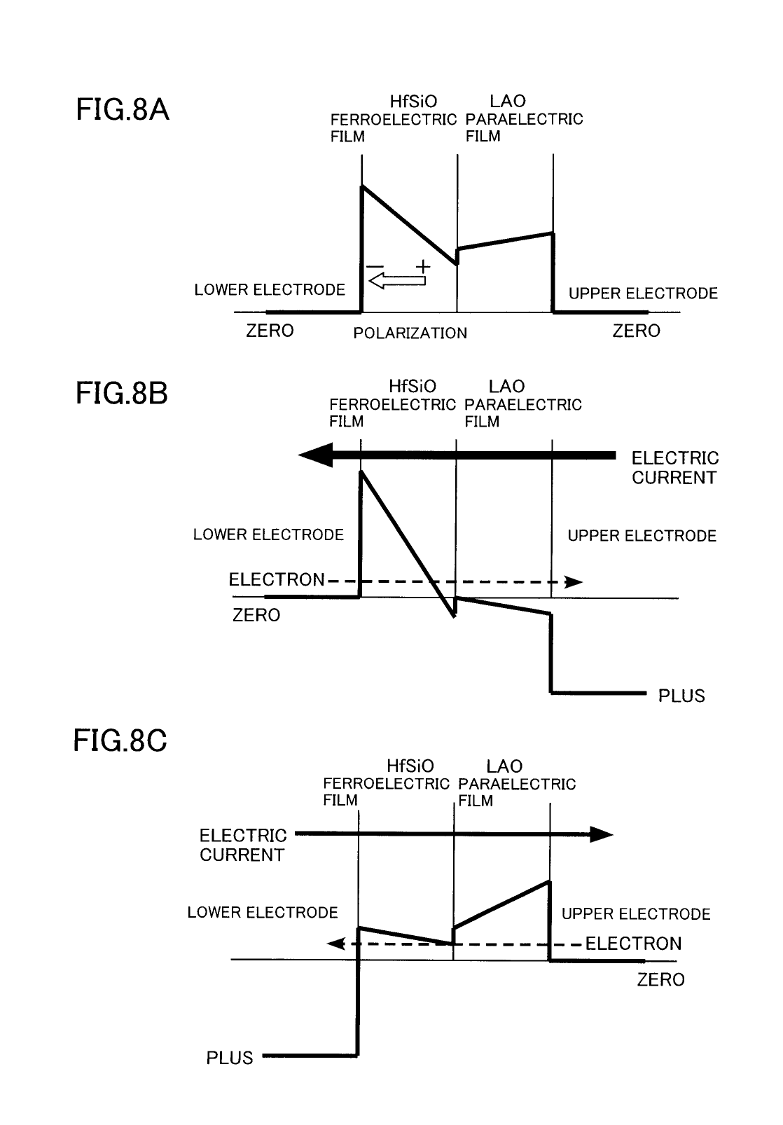

FIGS. 8A to 8C are explanatory diagrams of a rectification function of the non-volatile semiconductor device of the present embodiment. FIG. 8A illustrates a band structure of a memory cell of when a voltage is not applied between the electrodes. FIG. 8B illustrates a band structure of a memory cell of when a positive voltage is applied between the electrodes. FIG. 8C illustrates a band structure of a memory cell of when a negative voltage is applied between the electrodes.

FIGS. 8A to 8C illustrate Fermi levels of the lower electrode 12b and the upper electrode 14b, and lower ends of conductors of the ferroelectric film 16b and the paraelectric film 18b, by the sold thick lines. Further, a flow of a current is illustrated by the black arrow, and a polarizing direction of the ferroelectric film 16b is illustrated by the white arrow.

The dielectric constant of LAO as the paraelectric film 18b is higher than that of HfSiO as the ferroelectric film 16b. In other words, the dielectric constant of the ferroelectric film 16b is lower than that of the paraelectric film 18b. Therefore, similarly to the first embodiment, regarding the voltage applied between the upper electrode 14b and the lower electrode 12b, a higher ratio of voltage is applied to the ferroelectric film 16b having the lower dielectric constant. Therefore, change of the band structure of the paraelectric film 18b due to application of the voltage is smaller than that of the ferroelectric film 16b.

Therefore, as illustrated in FIG. 8B, when the positive voltage is applied to the upper electrode 14b, a barrier for allowing electrons to perform tunneling becomes relatively low. Therefore, a relatively large current flows from the upper electrode 14b to the lower electrode 12b. Meanwhile, as illustrated in FIG. 8C, when the positive voltage is applied to the lower electrode 12b, the change of the band structure of the paraelectric film 18b is small, and thus the barrier for allowing electrons to perform tunneling becomes relatively high. Therefore, a relatively small current flows from the lower electrode 12b to the upper electrode 14b.

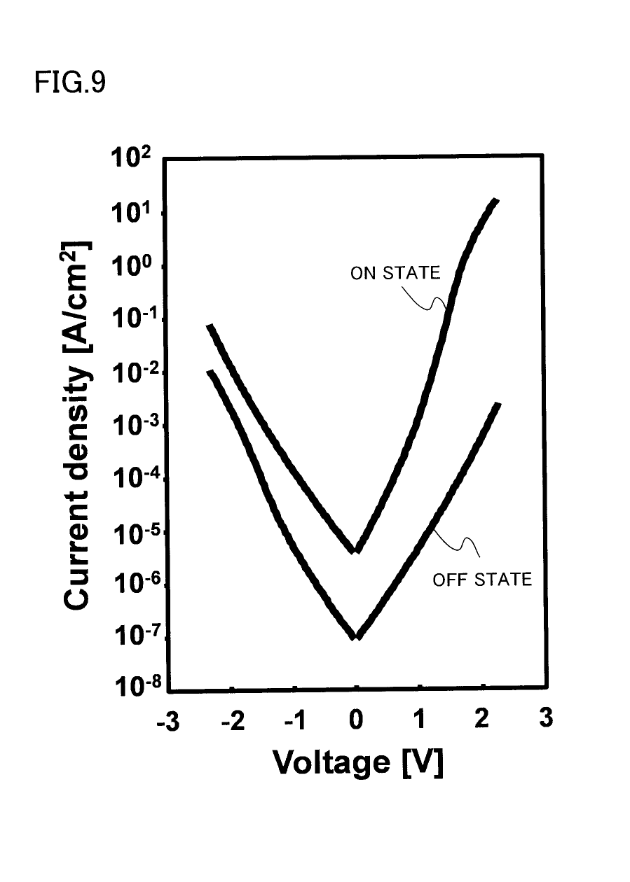

FIG. 9 is simulation results of current-voltage characteristics (I-V characteristics) of a memory cell of the present embodiment. The horizontal axis represents a voltage applied between the electrodes, and the vertical axis represents a current value flowing between the electrodes.

The simulation results are calculated where the film thickness of the hafnium oxide is 3.0 nm, and the film thickness of LAO is 3.0 nm. A voltage applying direction of when polarization in a high resistance state is formed is the positive voltage. A voltage applying direction of when polarization in a low resistance state is formed is the negative voltage. The simulation results of both cases of the low resistance state (ON state) and the high resistance state (OFF state) are calculated.

As illustrated in FIG. 9, in the memory cell of the present embodiment, the I-V characteristics are asymmetrical between the positive and negative voltage directions. Therefore, the memory cell of the present embodiment has a rectification function in the ON state.

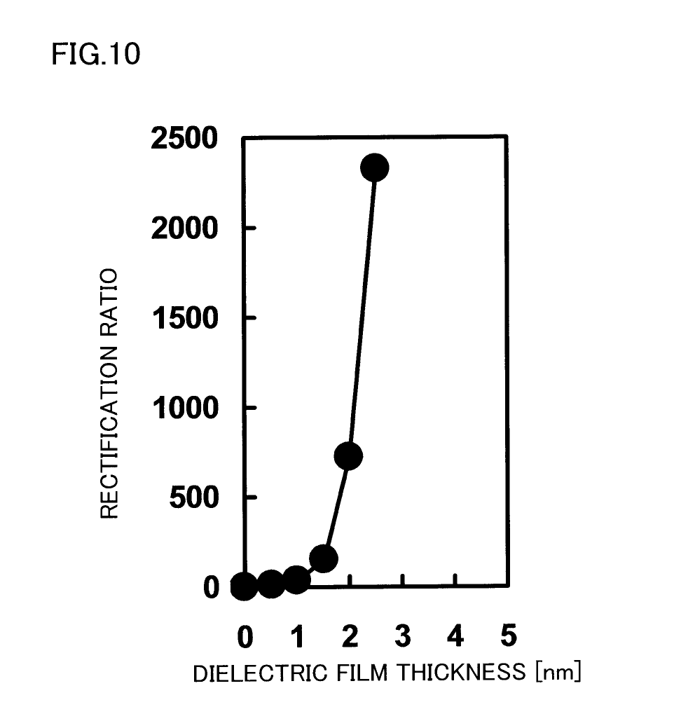

FIG. 10 is a simulation result of a relationship between a rectification ratio of a memory cell of the present embodiment, and the film thickness of a paraelectric film. The horizontal axis represents the film thickness of a paraelectric film, and the vertical axis represents the rectification ratio. The rectification ratio is a ratio of a forward direction current value and a reverse direction current value read at ±0.3 V. The film thickness of the hafnium oxide is fixed to 3.0 nm and the film thickness of LAO is changed at every 0.5 nm, and simulation is conducted.

As is clear from FIG. 10, when the film thickness of the paraelectric film 18b is thinner than 1.5 nm, rectification properties are not remarkable. However, when the film thickness is 1.5 nm or more, remarkable rectification properties begin to be exerted. Therefore, the film thickness of the paraelectric film 18b should be 1.5 nm or more. The film thickness of the paraelectric film 18b is desirably 2.0 nm or more, and more desirably 2.5 nm or more, from the perspective of enhancement of the rectification properties.

Further, the film thickness of the paraelectric film 18b is desirably 10 nm or less. If the film thickness exceeds the above range, a tunneling current does not flow, and a sufficient current value may not be able to be obtained when data is read out.

Note that the film thickness of the ferroelectric film 16b is minimum film thickness for causing the hafnium oxide to exert ferroelectricity, that is, 0.5 nm or more corresponding to one unit cell. Further, the film thickness is desirably from 1.0 nm or more to 10 nm or less. The film thickness of the ferroelectric film 16b is more desirably 2.0 nm or more. If the film thickness falls below the above range, stable and uniform ferroelectricity may not be able to be exerted. Further, when the film thickness exceeds the above range, the tunneling current does not flow, and the sufficient current value may not be able to be obtained when data is read out.

Further, a sum of the film thickness of the ferroelectric film 16b and the film thickness of the paraelectric film 18b is desirably 10 nm or less. If the film thickness exceeds this range, the tunneling current does not flow, and the sufficient current value may not be able to be obtained when data is read out. If the film thickness is thicker than 10 nm, conduction through defects in the film is mainly performed, and thus sufficient memory properties may not be able to be obtained.

As described above, according to the present embodiment, a non-volatile memory device including an FTJ having a resistance change function and a rectification function can be realized. Therefore, a non-volatile memory device in which scale-down of memory cells is easy can be realized.

Further, higher rectification properties than the first embodiment can obtained. Further, the hafnium oxide and LAO are proven materials in a preliminary step of a semiconductor manufacturing process, and having high process conformity with a first control circuit 26 and a second control circuit 28 configured from an electronic circuit using a semiconductor device. Therefore, the non-volatile memory device with scaled-down memory cells can be more easily manufactured.

### Third Embodiment

A non-volatile memory device of the present embodiment is similar to that of the second embodiment except that materials of a ferroelectric film and a paraelectric film, and a stacking order of aforementioned films. Therefore, description is omitted about contents overlapping with those of second embodiment.

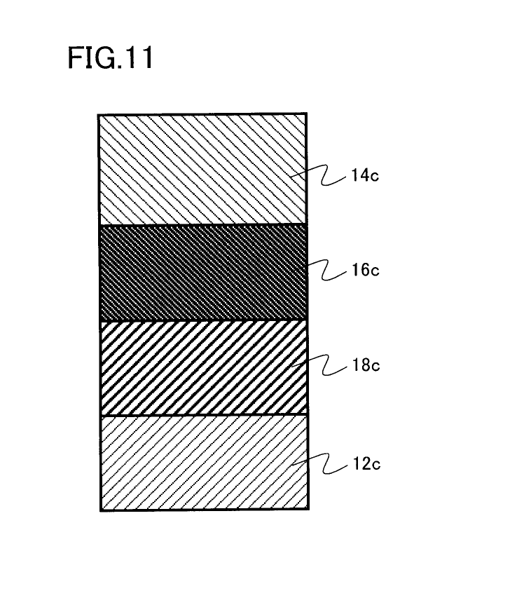

FIG. 11 is a schematic cross-sectional view of a memory cell of a non-volatile memory device of the present embodiment.

As illustrated in FIG. 11, the memory cell is a two-terminal FTJ sandwiched by a lower electrode (first conductive layer) 12c and an upper electrode (second conductive layer) 14c. The memory cell includes a ferroelectric film 16c between the lower electrode 12c and the upper electrode 14c. Further, the memory cell includes a paraelectric film 18c between the ferroelectric film 16c and the lower electrode 12c.

The lower electrode 12c and the upper electrode 14c are titanium nitride (TiN).

The ferroelectric film 16c is hafnium oxide (hafnia) containing silicon (Si). The dielectric constant of the hafnium oxide containing silicon (Si) is 11. Note that the hafnium oxide may contain at least one element selected from the group consisting of zircon (Zr), aluminum (Al), yttrium (Y), strontium (Sr), and gadolinium (Gd), other than Si. By containing of the above elements, ferroelectricity can be more easily exerted.

The paraelectric film 18c is tantalum oxide. The dielectric constant of the tantalum oxide is 22. The dielectric constant of the paraelectric film 18a is higher than that of the ferroelectric film 16c. Further, the band gap of the paraelectric film 18c is narrower than that of the ferroelectric film 16c.

Hereinafter, functions and effects of the non-volatile memory device of the present embodiment will be described.

In the memory cell of the present embodiment, I-V characteristics are asymmetrical between positive and negative voltage directions. Therefore, the memory cell of the present embodiment has a rectification function in an ON state.

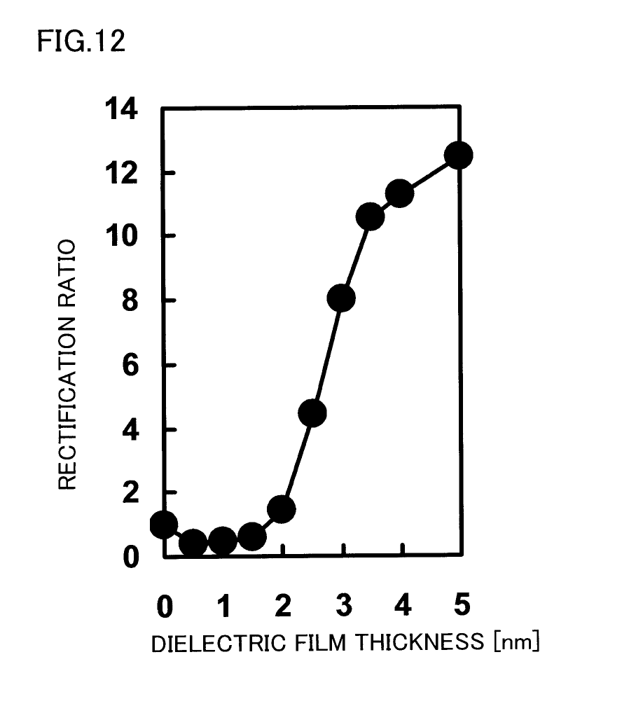

FIG. 12 is a simulation result of a relationship between a rectification ratio of a memory cell of the present embodiment, and film thickness of a paraelectric film. The horizontal axis represents the film thickness of a paraelectric film, and the vertical axis represents the rectification ratio. The rectification ratio is a ratio of a forward direction current value and a reverse direction current value read at ±0.3 V. The film thickness of the hafnium oxide is fixed to 3.0 nm and the film thickness of the tantalum oxide is changed at every 0.5 nm, and simulation is conducted.

As is clear from FIG. 12, when the film thickness of the paraelectric film 18c is thinner than 1.5 nm, rectification properties are not remarkable, but the rectification properties begin to be exerted when the film thickness is 1.5 nm or more. Therefore, the film thickness of the paraelectric film 18c should be 1.5 nm or more. The film thickness of the paraelectric film 18c is desirably 2.0 nm or more, and more desirably 2.5 nm or more, from the perspective of enhancement of the rectification properties.

As described above, according to the present embodiment, a non-volatile memory device including an FTJ having a resistance change function and a rectification function can be realized. Therefore, a non-volatile memory device in which scale-down of memory cells is easy can be realized.

Further, the hafnium oxide and the tantalum oxide are proven materials in a preliminary step of a semiconductor manufacturing process, and having high process conformity with a first control circuit 26 and a second control circuit 28 configured from an electronic circuit using a semiconductor device. Therefore, the non-volatile memory device with scaled-down memory cells can be more easily manufactured.

The film thickness of the ferroelectric film and the paraelectric film can be identified, for example, by measurement of the film thickness of a plurality of places with a transmission electron microscope (TEM), and calculation of an average values of the measurement results. Further, the materials of the ferroelectric film and the paraelectric film can be identified, for example, with a nanobeam diffractometry (NBD).

As described above, cases of using strontium titanate, lanthanum aluminum oxide, and tantalum oxide as the paraelectric film have been described in the embodiments. However, another material having a higher dielectric constant than the ferroelectric film, for example, titanium oxide or the like can be applied.

While certain embodiments have been described, these embodiments have been presented by way of example only, and are not intended to limit the scope of the inventions. Indeed, a non-volatile memory device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A non-volatile memory device comprising:
a first conductive layer;
a second conductive layer;
a ferroelectric film provided between the first conductive layer and the second conductive layer; and
a paraelectric film provided between one of the first conductive layer and the second conductive layer, and the ferroelectric film, the paraelectric film having film thickness of 1.5 nm or more and 10 nm or less, and the paraelectric film having a dielectric constant higher than the ferroelectric film.

2. The device according to claim 1, wherein film thickness of the ferroelectric film is 1.0 nm or more and 10 nm or less.

3. The device according to claim 1, wherein the ferroelectric film includes hafnium oxide.

4. The device according to claim 3, wherein the hafnium oxide contains at least one element selected from the group consisting of Zr, Al, Y, Sr, Si, and Gd.

5. The device according to claim 1, wherein the ferroelectric film includes barium titanate.

6. The device according to claim 1, wherein the paraelectric film includes lanthanum aluminum oxide, tantalum oxide, strontium titanate, or titanium oxide.

7. The device according to claim 1, wherein a sum of film thickness of the ferroelectric film and the film thickness of the paraelectric film is 10 nm or less.

8. The device according to claim 3, wherein the first conductive layer and the second conductive layer includes titanium nitride.

9. The device according to claim 1, wherein the film thickness of the paraelectric film is 2.0 nm or more.

10. A non-volatile memory device comprising:
a plurality of first wires;
a plurality of second wires intersecting with the first wires; and
a plurality of memory cells provided in regions where the first wires and the second wires intersect with each other, wherein
at least one of the memory cells includes a ferroelectric film and a paraelectric film provided between one of the first wires and one of the second wires, the paraelectric film having film thickness of 1.5 nm or more and 10 nm or less, the paraelectric film having a dielectric constant higher than the ferroelectric film.

11. The device according to claim 10, wherein film thickness of the ferroelectric film is 1.0 nm or more and 10 nm or less.

12. The device according to claim 10, wherein the ferroelectric film includes hafnium oxide.

13. The device according to claim 12, wherein the hafnium oxide contains at least one element selected from the group consisting of Zr, Al, Y, Sr, Si, and Gd.

14. The device according to claim 10, wherein the ferroelectric film includes barium titanate.

15. The device according to claim 10, wherein the paraelectric film includes lanthanum aluminum oxide, tantalum oxide, strontium titanate, or titanium oxide.

16. The device according to claim 10, wherein a sum of film thickness of the ferroelectric film and the film thickness of the paraelectric film is 10 nm or less.

17. The device according to claim 10, wherein the film thickness of the paraelectric film is 2.0 nm or more.
